(19) United States
(12) Patent Application Publication
(10) Pub. No.: US 2015/0014497 A1
(43) Pub. Date: Jan. 15, 2015

(54) MOUNTING APPARATUS FOR EXPANSION CARD

(71) Applicants: HONG FU JIN PRECISION INDUSTRY (ShenZhen) CO., LTD, Shenzhen (CN); HON HAI PRECISION INDUSTRY CO., LTD., New Taipei (TW)

(72) Inventor: ZHAN-YANG LI, Shenzhen (CN)

(73) Assignees: HONG FU JIN PRECISION INDUSTRY (ShenZhen) CO., LTD, Shenzhen (CN); HON HAI PRECISION INDUSTRY CO., LTD., New Taipei (TW)

(21) Appl. No.: 14/260,722

(22) Filed: Apr. 24, 2014

(30) Foreign Application Priority Data
Jul. 10, 2013 (CN) 2013102876631

(51) Int. Cl. H05K 7/14

(52) U.S. Cl. CPC H05K 7/1418
USPC 248/201

(57) ABSTRACT

A mounting apparatus for mounting a mounting bracket to an enclosure includes a sliding member, a resisting member, and a pushing member. A fixing hole is defined in the sliding member. A pressing portion partially covers the fixing hole. The mounting bracket includes a flange portion. An extension slot is defined in the enclosure. A supporting bracket extends from the enclosure above the extension slot. The sliding member prevents the resisting member from rotating relative to the enclosure, and the flange portion is secured between the resisting member and the supporting bracket. When the operation portion is pressed toward the enclosure, the pushing member passes through the fixing hole and resists against the pressing portion. The pushing member pushes the sliding member. The sliding member moves on the enclosure. The resisting member is rotated away from the supporting bracket, and the mounting bracket is detached from the supporting bracket.

### FIELD

The present disclosure relates to a mounting apparatus for an expansion card.

### BACKGROUND

Computers can include a number of expansion cards such as video cards, audio cards, and net cards. The expansion cards are mounted to a back plate of the computer case by a number of complicated locking structures.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded view of an embodiment of a mounting apparatus for expansion cards.

FIG. 2 is similar to FIG. 1, but viewed from a rear of the mounting apparatus.

FIG. 3 is an assembled view of the mounting apparatus for expansion cards of FIG. 1, with the mounting apparatus in a first position.

FIG. 4 is similar to FIG. 3, but viewed from a rear of the mounting apparatus.

FIG. 5 is an assembled view of the mounting apparatus for expansion cards of FIG. 1, with the mounting apparatus in a second position.

FIG. 6 is an assembled view of the mounting apparatus for expansion cards of FIG. 1, with the mounting apparatus in a third position.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

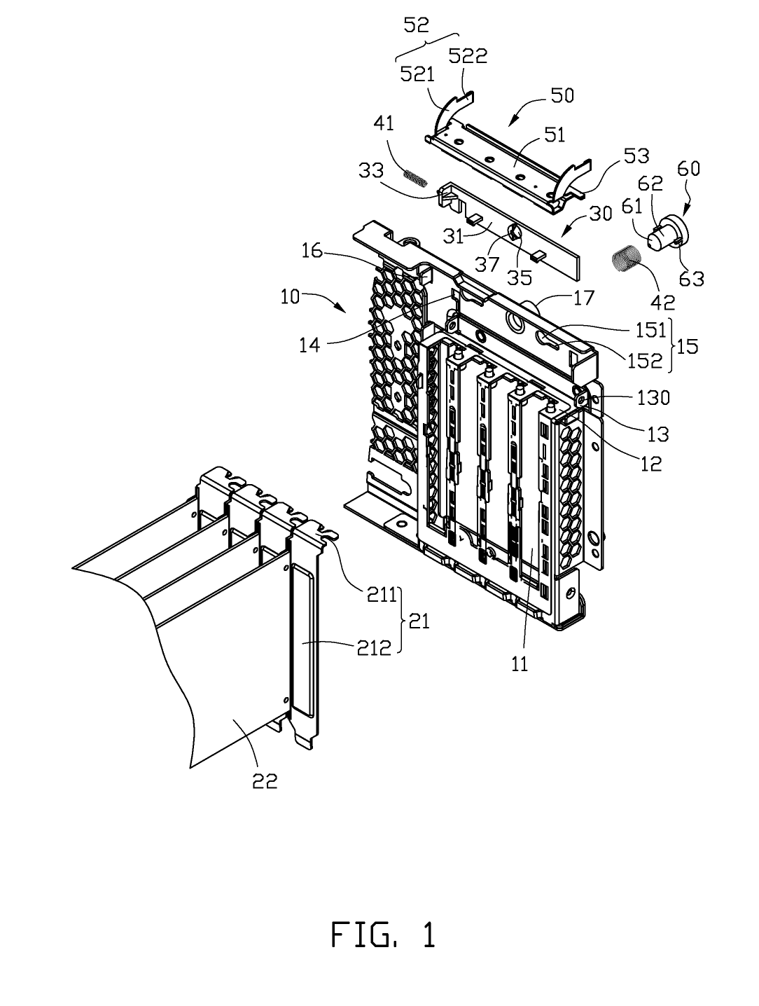

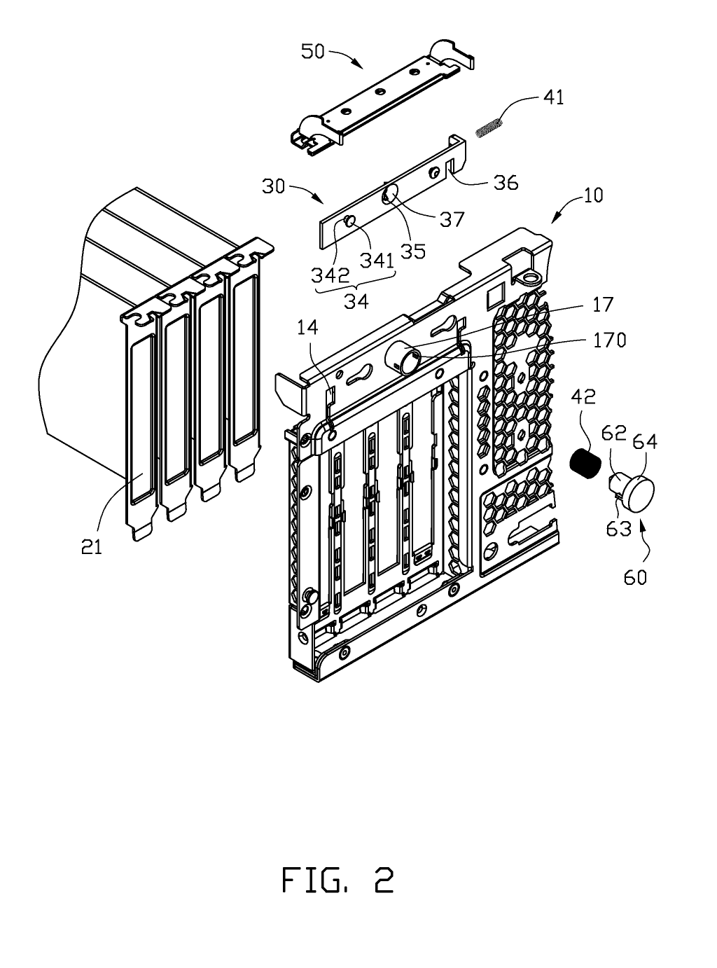

FIGS. 1-3 illustrate an embodiment of a mounting apparatus for mounting a number of mounting brackets 21 and expansion cards 22 to an enclosure 10. The mounting apparatus includes a sliding member 30, a resisting member 50, and a pushing member 60.

A number of extension slots 11 is defined in the enclosure 10. A number of supporting brackets 12 bound the number of extension slots 11. Two pivoting brackets 13 extend substantially perpendicularly from an inner side of the enclosure 10 above the number of supporting brackets 12. Each of the two pivoting brackets 13 defines a pivoting hole 130 therein. Two receiving slots 14 and two mounting holes 15 are defined in the enclosure 10 above the number of supporting brackets 12. In at least one embodiment, the two mounting holes 15 are located between the two receiving slots 14.

Each of the two mounting holes 15 includes an inserting portion 151 and a restriction portion 152 communicating with the inserting portion 151. A mounting portion 17 extends from an outer side of the enclosure 10. In at least one embodiment, the mounting portion 17 is a substantially hollow cylinder. The mounting portion 17 is located between the two mounting holes 15. Two locking holes 170 are defined in two sides of the mounting portion 17. An abutting bracket 16 extends from the inner side of the enclosure 10. In at least one embodiment, the abutting bracket 16 is located at an outer side of one of the two receiving slots 14.

In the embodiment, each mounting bracket 21 is substantially L-shaped. Each mounting bracket 21 includes a body 212 and a flange portion 211 extending substantially perpendicularly from a top end of the body 212.

The resisting member 50 includes a substantially rectangular resisting bracket 51. Two guiding brackets 52 and two rotating axles 53 extend from two sides of the resisting bracket 51. Each of the two guiding brackets 52 includes a stopping portion 521 connected to the resisting bracket 51, and a locating portion 522 extending from the stopping portion 521. In at least one embodiment, the resisting bracket 51 is substantially arc-shaped. A width of the stopping portion 521 is greater than a width of the locating portion 522.

The sliding member 30 includes a substantially rectangular sliding bracket 31. Two fixing members 34 are located on the sliding member 30 and correspond to the two mounting holes 15. Each of the two fixing members 34 includes a head portion 341 and a pole portion 342. The pole portion 342 is connected to the sliding bracket 31. A fixing hole 35 is defined in the sliding bracket 31 and corresponds to the mounting portion 17. A pressing portion 37 protrudes from an inner side of the sliding bracket 31 and partially covers the fixing hole 35. A fixing bracket 33 extends substantially perpendicularly from one end of the sliding bracket 31. A restriction slot 36 is defined in a bottom edge of the sliding bracket 31.

In at least one embodiment, a size of the head portion 341 is less than a size of the inserting portion 151, and greater than a size of the restriction portion 152. A size of the pole portion 342 is less than the size of the restriction portion 152. The pressing portion 37 is substantially arc-shaped. The fixing hole 35 is located between the two fixing members 34. The restriction slot 36 is adjacent to the fixing bracket 33.

The mounting apparatus further includes a first elastic member 41 and a second elastic member 42. In at least one embodiment, the first elastic member 41 and the second elastic member 42 are springs.

The pushing member 60 includes an operation portion 64 and a connection portion 62 connected to the operation portion 64. A substantially cone-shaped driving portion 61 extends from a distal end of the connection portion 62. Two locking portions 63 are located on the pushing member 60 and correspond to the two locking holes 170. In at least one embodiment, a diameter of the operation portion 64 is greater than a diameter of the mounting portion 17, and a diameter of the connection portion 62 is less than the diameter of the mounting portion 17.

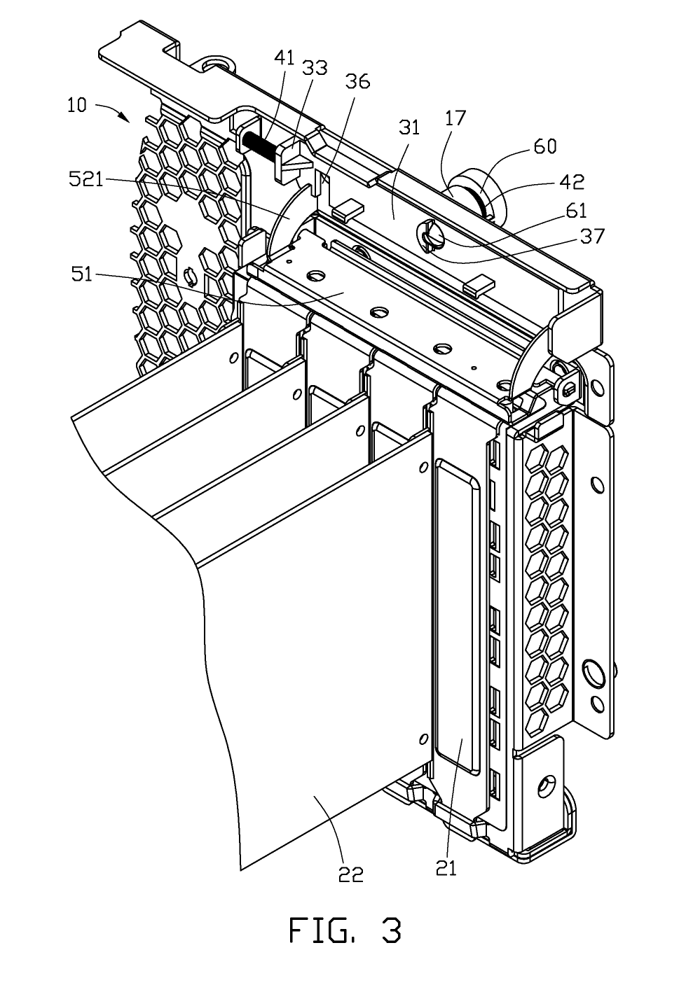

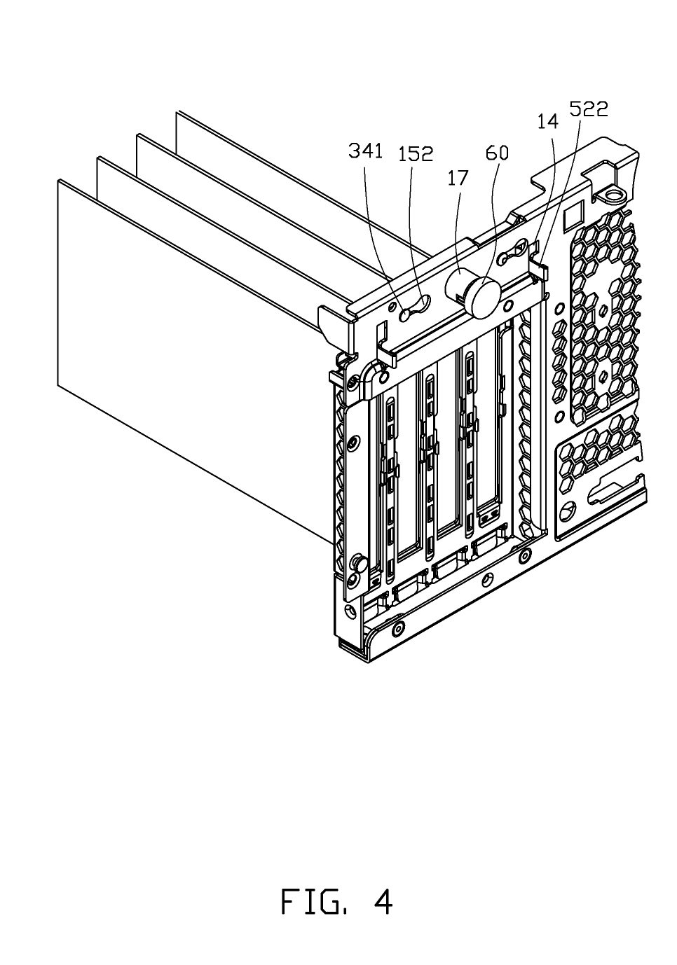

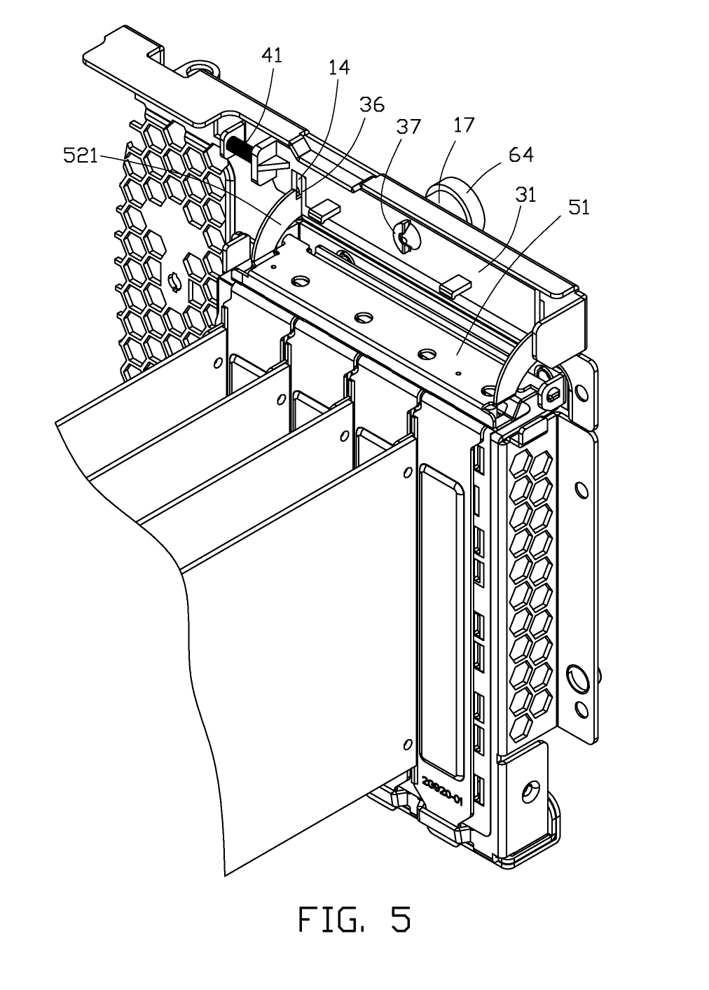

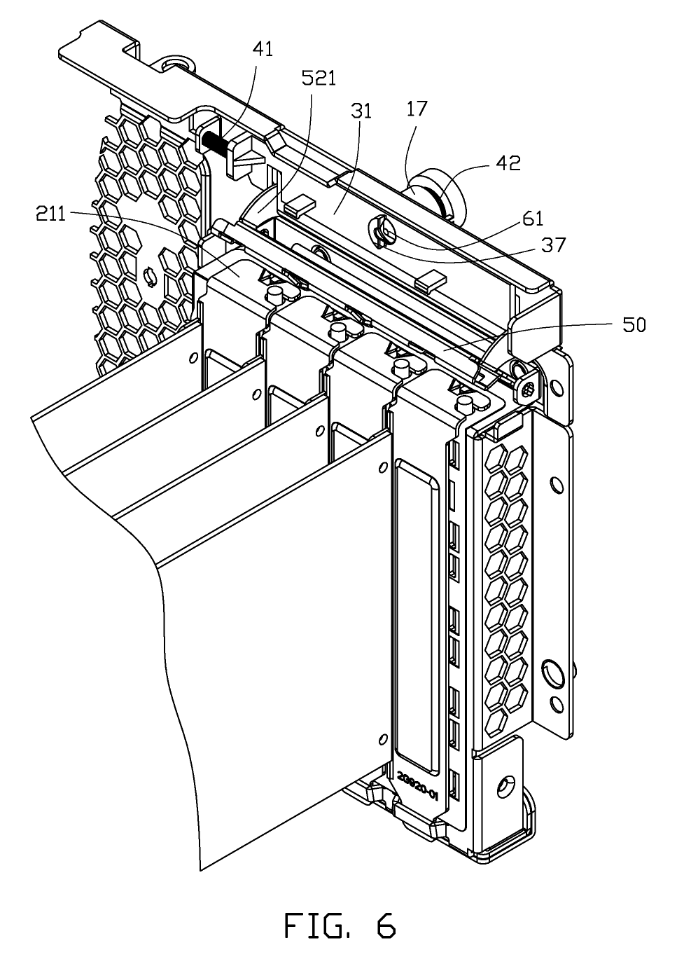

FIGS. 3-6 illustrate that, in assembly, the head portions 341 of the fixing member 34 pass through the corresponding inserting portions 151. The pole portions 342 are received in the corresponding inserting portions 151. A first terminal of the first elastic member 41 is mounted to the fixing bracket 33. A second terminal of the first elastic member 41 resists against the abutting bracket 16.

A distance from the abutting bracket 16 to the fixing bracket 33 is less than a relaxed length of the first elastic member 41. Thus, the first elastic member 41 pushes the sliding member 30. The sliding member 30 moves along a first direction on the enclosure 10, thereby causing the pole portions 342 to slide along the restriction portions 152 of the mounting holes 15, and causing the restriction slot 36 of the sliding bracket 31 to misalign with the receiving slot 14 of the enclosure 10. Thus, the sliding brackets 31 cover the upper portions of the corresponding receiving slots 14.

The two rotating axles 53 of the resisting member 50 are pivotably received in the pivoting holes 130 of the enclosure 10. The guiding brackets 52 of the resisting member 50 are aligned to the corresponding receiving slots 14. The locating portions 522 pass through a lower portion of the corresponding receiving slots 14. The sliding bracket 31 prevents the stopping portions 521 from passing through the corresponding receiving slots 14.

The second elastic member 42 is sleeved on the connection portion 62 of the pushing member 60. The assembled connection portion 62 and the second elastic member 42 are received in the mounting portion 17. The operation portion 64 is pressed to elastically deform the locking portions 63, thereby latching the locking portions 63 in the corresponding locking holes 170. The pushing member 60 is mounted to the mounting portion 17.

A first terminal of the second elastic member 42 resists against the enclosure 10 in the mounting portion 17. A second terminal of the second elastic member 42 resists against the operation portion 64. The second elastic member 42 pushes the locking portions 63. The locking portions 63 are latched in the corresponding locking holes 170. The driving portion 61 is misaligned with the pressing portion 37.

In use, the operation portion 64 is pressed toward the enclosure 10, thereby deforming the second elastic member 42. The locking portions 63 slide into the corresponding locking holes 170. The driving portion 61 passes through the fixing hole 35 and resists against the pressing portion 37. The driving portion 61 pushes the sliding member 30. The sliding member 30 moves along a second direction opposite to the first direction. Thus, the restriction slot 36 is aligned with the corresponding receiving slot 14.

The resisting member 50 is rotated to pass the stopping portions 521 through the corresponding receiving slots 14. The operation portion 64 is released, and the second elastic member 42 is restored to latch the locking portions 63 in the corresponding locking holes 170. The stopping portions 521 prevent the sliding member 30 from moving back along the first direction. The mounting brackets 21 and the expansion cards 22 are mounted in the extension slots 11. The flange portions 211 of the mounting brackets 21 contact the corresponding supporting brackets 12.

The resisting member 50 is rotated to move the stopping portions 521 out of the receiving slots 14. The first elastic member 41 pushes the sliding member 30. The sliding member 30 moves back along the first direction, causing the restriction slot 36 to misalign with the corresponding receiving slot 14. The sliding bracket 31 prevents the stopping portions 521 from passing through the receiving slots 14. The flange portion 211 is secured between the resisting bracket 51 and the supporting brackets 12.

In disassembly, the operation portion 64 is pressed to align the restriction slot 36 with the corresponding receiving slot 14. The resisting member 50 is rotated to pass the stopping portions 521 through the receiving slots 14. Thus, the mounting brackets 21 and the expansion cards 22 can be detached from the corresponding supporting brackets 12.

Even though numerous characteristics and advantages of the present disclosure have been set forth in the foregoing description, together with details of the structure and function of the disclosure, the disclosure is illustrative only, and changes may be made in detail, including in the matters of shape, size, and the arrangement of parts within the principles of the disclosure to the full extent indicated by the broad general meaning of the terms in which the appended claims are expressed.

What is claimed is:

1. A mounting apparatus for mounting a mounting bracket on an enclosure, comprising:
a sliding member slidably mounted to the enclosure, wherein a fixing hole is defined in the sliding member, and a pressing portion extends out from the fixing hole;
a resisting member pivotably mounted to the enclosure; and
a pushing member mounted to the enclosure, wherein the mounting bracket comprises a flange portion, an extension slot is defined in the enclosure, a supporting bracket bends from the enclosure above the extension slot, the sliding member prevents the resisting member rotating relative to the enclosure, the flange portion is remained between the resisting member and the supporting bracket, and when the operation portion is pressed toward the enclosure, the pushing member passes through the fixing hole and resists against the pressing portion, the pushing member pushes the sliding member, the sliding member moves on the enclosure, the resisting member is rotated away from the supporting bracket, the mounting bracket is detached from the supporting bracket.

2. The mounting apparatus of claim 1, wherein the pushing member comprises a driving portion corresponding to the pressing portion, the driving portion is substantially cone-shaped, and the pressing portion is substantially arc-shaped.

3. The mounting apparatus of claim 2, further comprising a first elastic member connected to the enclosure and the sliding member, and the first elastic member pushes the sliding member move on the enclosure.

4. The mounting apparatus of claim 3, further comprising a second elastic member connected to the enclosure and the pushing member, and the second elastic member is elastically deformed when the pushing member resists against the pressing portion.

5. The mounting apparatus of claim 4, further comprising a mounting portion extends from the enclosure corresponding to the fixing hole, the mounting portion comprises two locking holes defined in two sides of the mounting portion, two locking portions are located on the pushing member corresponding to the two locking holes, and the locking portions are locked in the corresponding locking holes.

6. The mounting apparatus of claim 5, wherein the pushing member further comprises a connection portion connected to the driving portion, the second elastic member is mounted to the connection portion, and the connection portion and the second elastic member are located in the mounting portion.

7. The mounting apparatus of claim 6, further comprising a mounting hole defined in the enclosure, a fixing member is located on the sliding member corresponding to the mounting hole, and the fixing member is received in the mounting hole.

8. A mounting apparatus for mounting a mounting bracket, comprising:
an enclosure defining an extension slot therein, wherein a supporting bracket bends from the enclosure above the extension slot;
a sliding member slidably mounted to the enclosure, wherein a fixing hole is defined in the sliding member, a pressing portion extends out from the fixing hole;
a resisting member pivotably mounted to the enclosure; and
a pushing member mounted to the enclosure, wherein the mounting bracket comprises a flange portion, the sliding member prevents the resisting member rotating relative to the enclosure, the flange portion is remained between the resisting member and the supporting bracket, and when the operation portion is pressed toward the enclosure, the pushing member passes through the fixing hole and resists against the pressing portion, the pushing member pushes the sliding member; the sliding member moves on the enclosure, the resisting member is rotated away from the supporting bracket, the mounting bracket is detached from the supporting bracket.

9. The mounting apparatus of claim 8, wherein the pushing member comprises a driving portion corresponding to the pressing portion, the driving portion is substantially cone-shaped, and the pressing portion is substantially arc-shaped.

10. The mounting apparatus of claim 9, further comprising a first elastic member connected to the enclosure and the sliding member, and the first elastic member pushes the sliding member move on the enclosure.

11. The mounting apparatus of claim 10, further comprising a second elastic member connected to the enclosure and the pushing member, and the second elastic member is elastically deformed when the pushing member resists against the pressing portion.

12. The mounting apparatus of claim 11, further comprising a mounting portion extends from the enclosure corresponding to the fixing hole, the mounting portion comprises two locking holes defined in two sides of the mounting portion, two locking portions are located on the pushing member corresponding to the two locking holes, and the locking portions are locked in the corresponding locking holes.

13. The mounting apparatus of claim 12, wherein the pushing member further comprises a connection portion connected to the driving portion, the second elastic member is mounted to the connection portion, and the connection portion and the second elastic member are located in the mounting portion.

14. The mounting apparatus of claim 13, further comprising a mounting hole defined in the enclosure, a fixing member is located on the sliding member corresponding to the mounting hole, and the fixing member is received in the mounting hole.
